(19) United States
(12) Patent Application Publication
(10) Pub. No.: US 2025/0123332 A1
(43) Pub. Date: Apr. 17, 2025

(54) BATTERY MANAGEMENT APPARATUS AND OPERATING METHOD OF THE SAME

(71) Applicant: LG ENERGY SOLUTION, LTD., Seoul (KR)

(72) Inventors: Guang Ri LI, Daejeon (KR); Bom Jin LEE, Daejeon (KR)

(21) Appl. No.: 18/918,868

(22) Filed: Oct. 17, 2024

(30) Foreign Application Priority Data
Oct. 17, 2023 (KR) 10-2023-0138529

(51) Int. Cl. G01R 31/389; G01R 31/3842; H02J 7/00

(52) U.S. Cl. CPC G01R 31/389; G01R 31/3842; H02J 7/0048

(57) ABSTRACT

A battery management apparatus according to an embodiment disclosed in this document may include an information acquisition unit that acquires a voltage of each of a plurality of battery cells, and a controller that calculates a resistance of each of the plurality of battery cells corresponding to a SOC class including at least one SOC based on the voltage of each of the plurality of battery cells when the plurality of battery cells are charged based on a preset charging protocol and diagnoses each of the plurality of battery cells based on the resistance of each of the plurality of battery cells corresponding to the SOC class.

### CROSS-REFERENCE TO RELATED APPLICATIONS

This application claims priority to, and the benefit of, Korean Patent Application No. 10-2023-0138529 filed on Oct. 17, 2023 in the Korean Intellectual Property Office, the disclosure of which is incorporated herein by reference in its entirety.

### TECHNICAL FIELD

The present disclosure relates to a battery management apparatus and an operating method of the same.

### BACKGROUND

Recently, research and development on secondary batteries are being actively conducted. Here, the secondary batteries are batteries that can be charged and discharged, and can include both Ni/Cd batteries and Ni/MH batteries, as well as lithium-ion batteries. Among the various types of secondary batteries, the lithium-ion batteries have an advantage of having a much higher energy density compared to Ni/Cd batteries, Ni/MH batteries, and other types of batteries. In addition, the lithium-ion batteries can be manufactured to be small and lightweight and, therefore, can be used as a power source for mobile devices. Recently, their range of use has been extended to power sources for electric vehicles, and they are attracting attention as a next-generation energy storage medium.

While lithium-ion batteries may be desired for various devices and use cases, the development and usage of lithium-ion batteries presents challenges associated with lithium precipitation (also known as lithium plating). Lithium precipitation conditions may occur when lithium ions are deposited as metallic lithium on a surface of an anode in a lithium-ion battery, rather than intercalating into the anode material. This phenomenon can negatively impact performance of lithium-ion batteries and, in more severe cases, can create fire risks or hazards.

Current technologies for diagnosing lithium precipitation in batteries typically require extensive time periods to accurately diagnose precipitation conditions. For example, some technologies, such as those that rely on open circuit voltage (OCV) for diagnosing lithium precipitation, require a long rest time due to the characteristics of OCV. Therefore, in order to satisfy users who actually use batteries, a diagnostic charging protocol may be desired that has a similar diagnosis time as the normal charging time for the batteries.

The background description provided herein is for the purpose of generally presenting context of the disclosure. Unless otherwise indicated herein, the materials or technologies described in this section are not prior art to the claims in this application and are not admitted to be prior art, or suggestions of the prior art, by inclusion in this section.

### SUMMARY

An aspect of the present disclosure provides a battery management apparatus that can diagnose a plurality of battery cells during charging through a diagnostic charging protocol, and an operating method of the same.

Another aspect of the present disclosure provides a battery management apparatus that can calculate a resistance of each of a plurality of battery cells corresponding to a state of charge (SOC) and diagnose the plurality of battery cells based on the calculated resistance, and an operating method of the same.

The technical problems to be solved of the embodiments disclosed in this document are not limited to the technical problems to be solved mentioned above, and other technical problems to be solved not mentioned will be clearly understood by those skilled in the art from the description below.

In certain embodiments, a system for diagnosing an abnormal battery condition can comprise: (a) an information acquisition unit configured to acquire voltage values for each of a plurality of battery cells associated with a state of charge (SOC) class, wherein the voltage values are determined while the plurality of battery cells are being charged; and (b) a controller configured to: (1) determine a resistance value for each of the plurality of battery cells associated with the SOC class based on the voltage values acquired during charging of the plurality of battery cells; and (2) detect whether an abnormal battery condition is present for each of the plurality of battery cells associated with the SOC class based, at least in part, on the resistance value determined for each of the plurality of battery cells.

In certain embodiments, detecting whether the abnormal battery condition is present can include detecting whether a lithium precipitation condition is present for each of the plurality of battery cells associated with the SOC class based, at least in part, on the resistance value determined for each of the plurality of battery cells associated with the SOC class.

Additionally, or alternatively, detecting whether the abnormal battery condition is present can include determining whether one or more of the following conditions are present: a dendrite growth, a short circuit, and a thermal runaway.

In certain embodiments, the controller can be further configured to: (1) determine first average resistance values for the plurality of battery cells associated with the SOC class, wherein each first average resistance value is derived from a plurality of resistance values measured for a corresponding battery cell; (2) determine a second average resistance value for the plurality of battery cells associated with the SOC class, wherein the second average resistance value is derived by averaging the first average resistance values for the plurality of battery cells; and (3) for each of the plurality of battery cells associated with the SOC class, detect whether the abnormal battery condition is present based, at least in part, on the first average resistance value for the corresponding battery cell and the second average resistance value calculated across the plurality of battery cells.

In certain embodiments, the controller can be further configured to: (1) for each of the plurality of battery cells associated with the SOC class, determine a probability distribution based on the plurality of resistance values measured for a corresponding battery cell and the second average resistance value calculated across the plurality of battery cells; and (2) detect whether the abnormal battery condition is present for each of the plurality of battery cells based, at least in part, on the probability distribution determined for the corresponding battery cell.

In certain embodiments, the controller can be further configured to: (1) for each of the plurality of battery cells associated with the SOC class, determine a standard deviation based on the plurality of resistance values measured for a corresponding battery cell and the second average resistance value calculated across the plurality of battery cells, and (2) detect whether the abnormal battery condition is present for each of the plurality of battery cells based, at least in part, on the standard deviation.

In certain embodiments, for each of the plurality of battery cells associated with the SOC class, the plurality of resistance values for the corresponding battery cell can be determined when the corresponding battery cell reaches different SOC values during charging, and the first average resistance value for the corresponding battery cell can be based on the plurality of resistance values obtained at the different SOC values.

In certain embodiments, the abnormal condition can correspond to a lithium precipitation condition, and the controller can be configured to detect whether the lithium precipitation condition is present in each of the plurality of battery cells using the first average resistance value for the corresponding battery cell and the second average resistance value calculated across the plurality of battery cells.

In certain embodiments, the plurality of battery cells associated with the SOC class can be charged according to a charging protocol, and the charging protocol can be configured to repeatedly transition between: a) a charging state in which the plurality of battery cells are charged at a first C-rate; and b) a resting state. The controller can be configured to determine the resistance value for each of the plurality of battery cells while charging the plurality of battery cells at the first C-rate in the charging state.

In certain embodiments, the controller can be further configured to: (1) determine an amount of change between the voltage values acquired for each of the plurality of battery cells during a first charging state for a first time period and a second charging state for a second time period; and (2) determine the resistance value for each of the plurality of battery cells based on a charging current applied to each of the plurality of battery cells and the change in voltage values for each of the plurality of battery cells.

In certain embodiments, the plurality of battery cells associated with the SOC class are charged according to a charging protocol, and the charging protocol can be configured to repeatedly transition between: a) a first charging state in which the plurality of battery cells are charged at a first C-rate; and b) a second charging state in which the plurality of battery cells are charged at a second C-rate. The second C-rate can be smaller than the first C-rate, and the controller can be configured to determine the resistance value for each of the plurality of battery cells while charging the plurality of battery cells at the first C-rate in the first charging state.

In certain embodiments, the information acquisition unit and the controller are incorporated into a battery management system (BMS) for a battery pack that comprises the plurality of battery cells, or the information acquisition unit and the controller are incorporated into a cloud server, battery management server, or computing device that is external to the battery pack that comprises the plurality of battery cells.

In certain embodiments, a method for diagnosing an abnormal battery condition can include: (a) acquiring voltage values for each of the plurality of battery cells associated with a state of charge (SOC) class, wherein the voltage values are determined while the plurality of battery cells are being charged; (b) determining a resistance value for each of the plurality of battery cells associated with the SOC class based on the voltage values acquired during charging of the plurality of battery cells; and (c) detecting whether an abnormal battery condition is present for each of the plurality of battery cells associated with the SOC class based, at least in part, on the resistance value determined for each of the plurality of battery cells.

In certain embodiments, detecting whether the abnormal battery condition is present can include detecting whether a lithium precipitation condition is present for each of the plurality of battery cells associated with the SOC class based, at least in part, on the resistance value determined for each of the plurality of battery cells associated with the SOC class.

In certain embodiments, the method can further comprise: (1) determining first average resistance values for the plurality of battery cells associated with the SOC class, wherein each first average resistance value is derived from a plurality of resistance values measured for a corresponding battery cell; (2) determining a second average resistance value for the plurality of battery cells associated with the SOC class, wherein the second average resistance value is derived by averaging the first average resistance values for the plurality of battery cells; and (3) for each of the plurality of battery cells associated with the SOC class, detecting whether the abnormal battery condition is present based, at least in part, on the first average resistance value for the corresponding battery cell and the second average resistance value calculated across the plurality of battery cells.

In certain embodiments, the method can further comprise: (1) for each of the plurality of battery cells associated with the SOC class, determining a probability distribution based on the plurality of resistance values measured for a corresponding battery cell and the second average resistance value calculated across the plurality of battery cells; and (2) detecting whether the abnormal battery condition is present for each of the plurality of battery cells based, at least in part, on the probability distribution determined for the corresponding battery cell.

In certain embodiments, the method can further comprise: (1) for each of the plurality of battery cells associated with the SOC class, determining a standard deviation based on the plurality of resistance values measured for a corresponding battery cell and the second average resistance value calculated across the plurality of battery cells; and (2) detecting whether the abnormal battery condition is present for each of the plurality of battery cells based, at least in part, on the standard deviation.

In certain embodiments, the plurality of resistance values for the corresponding battery cell can be determined when the corresponding battery cell reaches different SOC values during charging, and the first average resistance value for the corresponding battery cell can be based on the plurality of resistance values obtained at the different SOC values.

In certain embodiments, the method can further comprise: 1) charging the plurality of battery cells associated with the SOC class according to a charging protocol, wherein the charging protocol is configured to repeatedly transition between: a) a charging state in which the plurality of battery cells are charged at a first C-rate; and b) a resting state; 2) determining an amount of change between the voltage values acquired for each of the plurality of battery cells during a first charging state for a first time period and a second charging state for a second time period; and 3) determining the resistance value for each of the plurality of battery cells based on a charging current applied to each of the plurality of battery cells and the change in voltage values for each of the plurality of battery cells.

In certain embodiments, the method can further comprise: 1) charging the plurality of battery cells associated with the SOC class according to a charging protocol, wherein: (a) the charging protocol is configured to repeatedly transition between: a) a first charging state in which the plurality of battery cells are charged at a first C-rate; and b) a second charging state in which the plurality of battery cells are charged at a second C-rate; and (b) the second C-rate is smaller than the first C-rate; and (2) determining the resistance value for each of the plurality of battery cells while charging the plurality of battery cells at the first C-rate in the first charging state.

In certain embodiments, a system for diagnosing a lithium precipitation condition can comprise: (a) an information acquisition unit configured to acquire voltage values for each of a plurality of battery cells associated with a state of charge (SOC) class, wherein the voltage values are determined while the plurality of battery cells are being charged; and (b) a controller configured to: (1) determine a resistance value for each of the plurality of battery cells associated with the SOC class based on the voltage values acquired during charging of the plurality of battery cells; and (2) detect whether a lithium precipitation condition is present for each of the plurality of battery cells associated with the SOC class based, at least in part, on the resistance value determined for each of the plurality of battery cells.

According to an aspect of the present disclosure, there is provided a battery management apparatus including an information acquisition unit that acquires a voltage of each of a plurality of battery cells, and a controller that calculates a resistance of each of the plurality of battery cells corresponding to a SOC class including at least one SOC based on the voltage of each of the plurality of battery cells when the plurality of battery cells are charged based on a preset charging protocol and diagnoses each of the plurality of battery cells based on the resistance of each of the plurality of battery cells corresponding to the SOC class.

In an embodiment, the controller may calculate a first average resistance of each of the plurality of battery cells which corresponds to an average of resistances corresponding to the SOC class for each of the plurality of battery cells, calculate a second average resistance corresponding to an average of the first average resistance of each of the plurality of battery cells, and diagnose each of the plurality of battery cells based on the first average resistance and the second average resistance of each of the plurality of battery cells.

In an embodiment, the controller may calculate a probability distribution of the first average resistance of each of the plurality of battery cells based on the first average resistance and the second average resistance of each of the plurality of battery cells, and diagnose each of the of battery cells based on the probability plurality distribution.

In an embodiment, the controller may calculate a standard deviation of the first average resistance of each of the plurality of battery cells based on the second average resistance, and diagnose that lithium precipitation has occurred in a battery cell having the first average resistance that differs from the second average resistance by a set deviation or more.

In an embodiment, the charging protocol may be configured to repeat a charging method of charging as much as a first SOC at a first C-rate and resting for a first time.

In an embodiment, the controller may calculate the resistance of each of the plurality of battery cells while charging the plurality of battery cells at the first C-rate.

In an embodiment, the controller may calculate an amount of change in voltage of each of the plurality of battery cells for a second time when charging the plurality of battery cells at the first C-rate, and calculate the resistance of each of the plurality of battery cells by dividing the change in voltage of each of the plurality of battery cells by a charging current.

In an embodiment, the charging protocol may be configured to repeat a charging method of charging as much as a first SOC at a first C-rate and charging for a time set at a second C-rate, and the second C-rate may be smaller than the first C-rate.

In an embodiment, the controller may calculate the resistance of each of the plurality of battery cells while charging the plurality of battery cells at the first C-rate.

According to another aspect of the present disclosure, there is provided an operating method of a battery management apparatus, the method including an operation of acquiring a voltage of each of a plurality of battery cells, an operation of calculating a resistance of each of the plurality of battery cells corresponding to a SOC class including at least one SOC based on the voltage of each of the plurality of battery cells when the plurality of battery cells are charged based on a preset charging protocol, and an operation of diagnosing each of the plurality of battery cells based on the resistance of each of the plurality of battery cells corresponding to the SOC class.

In an embodiment, the operation of diagnosing each of the plurality of battery cells based on the resistance of each of the plurality of battery cells corresponding to the SOC class may include an operation of calculating a first average resistance of each of the plurality of battery cells which corresponds to an average of resistances corresponding to the SOC class for each of the plurality of battery cells, and an operation of calculating a second average resistance corresponding to an average of the first average resistance of each of the plurality of battery cells.

In an embodiment, the operation of diagnosing each of the plurality of battery cells based on the resistance of each of the plurality of battery cells corresponding to the SOC class may further include an operation of calculating a probability distribution of the first average resistance of each of the plurality of battery cells based on the first average resistance and the second average resistance of each of the plurality of battery cells, and an operation of diagnosing each of the plurality of battery cells based on the probability distribution.

In an embodiment, the operation of diagnosing each of the plurality of battery cells based on the resistance of each of the plurality of battery cells corresponding to the SOC class may further include an operation of calculating a standard deviation of the first average resistance of each of the plurality of battery cells based on the second average resistance, and an operation of diagnosing that lithium precipitation has occurred in a battery cell having the first average resistance that differs from the second average resistance by a set deviation or more.

In an embodiment, the charging protocol may be configured to repeat a charging method of charging as much as a first SOC at a first C-rate and resting for a first time.

In an embodiment, in the operation of calculating a resistance of each of the plurality of battery cells corresponding to a SOC class including at least one SOC based on the voltage of each of the plurality of battery cells when the plurality of battery cells are charged based on a preset charging protocol, the resistance of each of the plurality of battery cells may be calculated while charging the plurality of battery cells at the first C-rate.

In an embodiment, the operation of calculating a resistance of each of the plurality of battery cells corresponding to a SOC class including at least one SOC based on the voltage of each of the plurality of battery cells when the plurality of battery cells are charged based on a preset charging protocol may include an operation of calculating an amount of change in voltage of each of the plurality of battery cells for a second time when charging the plurality of battery cells at the first C-rate, and an operation of calculating the resistance of each of the plurality of battery cells by dividing the change in voltage of each of the plurality of battery cells by a charging current.

In an embodiment, the charging protocol may be configured to repeat a charging method of charging as much as a first SOC at a first C-rate and charging for a time set at a second C-rate, and the second C-rate may be smaller than the first C-rate.

In an embodiment, in the operation of calculating a resistance of each of the plurality battery cells corresponding to a SOC class including at least one SOC based on the voltage of each of the plurality of battery cells when the plurality of battery cells are charged based on a preset charging protocol, the resistance of each of the plurality of battery cells may be calculated while charging the plurality of battery cells at the first C-rate.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram showing a configuration of a general battery pack.

FIG. 2 is a block diagram showing a battery management apparatus according to an embodiment disclosed in this document.

FIG. 3 is a diagram showing an example of a charging protocol according to an embodiment disclosed in this document.

FIG. 4 is a diagram showing an example in which a plurality of battery cells are diagnosed by the battery management apparatus according to an embodiment disclosed in this document.

FIG. 5 is a diagram showing an example in which a plurality of battery cells are diagnosed by the battery management apparatus according to an embodiment disclosed in this document.

FIG. 6 is a flowchart showing an operating method of the battery management apparatus according to an embodiment disclosed in this document.

FIG. 7 is a flowchart illustrating an exemplary operating method of a battery management apparatus according to an embodiment.

FIG. 8 is a flowchart illustrating an exemplary operating method of a battery management apparatus according to an embodiment.

FIG. 9 is a flowchart illustrating an exemplary operating method of a battery management apparatus according to an embodiment.

FIG. 10 is a flowchart illustrating an exemplary operating method of a battery management apparatus according to an embodiment.

FIG. 11 is a block diagram showing an exemplary hardware configuration of a computing system for performing the operating method(s) of a battery management apparatus according to an embodiment.

### DETAILED DESCRIPTION

Exemplary embodiments will now be described in detail with reference to the accompanying drawings.

Hereinafter, embodiments disclosed in this document will be described in detail through exemplary drawings. When adding reference numerals to components in each drawing, it should be noted that the same components are given the same reference numerals as much as possible even if they are shown in different drawings. In addition, in describing the embodiments disclosed in this document, if it is determined that detailed descriptions of related known configurations or functions impede understanding of the embodiments disclosed in this document, the detailed descriptions thereof will be omitted.

In describing the components of the embodiment disclosed in this document, terms such as first, second, A, B, (a), (b), etc. may be used. These terms are only used to distinguish the component from other components, and the nature, sequence, or order of the component is not limited by the terms. In addition, unless otherwise defined, all terms used herein, including technical or scientific terms, have the same meaning as commonly understood by a person of ordinary skill in the technical field to which the embodiments disclosed in this document pertain. Terms that are defined in commonly used dictionaries are such as those defined in the dictionary should be interpreted as having a meaning consistent with the meaning in the context of the related technology, and unless clearly defined in this application, should not be interpreted in an ideal or excessively formal sense.

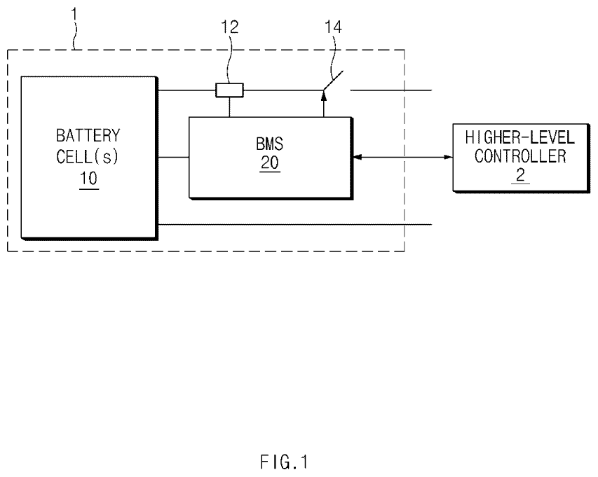

FIG. 1 is a block diagram showing a configuration of a general battery pack.

Referring to FIG. 1, a battery control system including a battery pack 1 and a higher-level controller 2 included in a higher-level system according to an embodiment of the present disclosure is schematically shown.

As shown in FIG. 1, the battery pack 1 includes one or more battery cells 10 and, in many cases, a plurality of battery cells 10. Each of the one or more battery cells 10 are capable of being charged and discharged. The battery pack 1 further comprises a switching unit 14 connected in series to a positive terminal side or a negative terminal side of the plurality of battery cells 10 to control the flow of charge and discharge current of the plurality of battery cells 10, and a battery management system 20 that monitors the voltage, current, and temperature of the battery pack 1 and controls it to prevent overcharging and overdischarging. In this case, the battery pack 1 may be provided with a plurality of battery cells 10, a plurality of sensors 12, a plurality of switching units 14, and a plurality of battery management system 20.

In this example, the switching unit 14 can include an element for controlling the current flow for charging or discharging of the plurality of battery cells 10. For example, depending on the specifications of the battery pack 1, the switching unit 14 may include at least one relay, at least one magnetic contactor, etc.

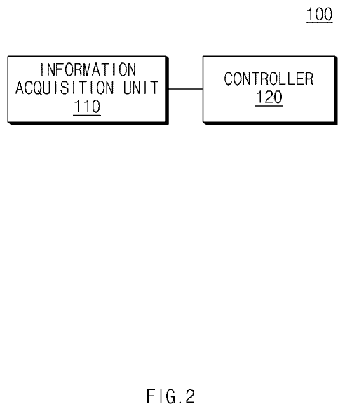

The battery management system 20 is an interface that receives measured values of various parameters described above as inputs, and may include a plurality of terminals, a circuit connected to these terminals to process the received values, etc. In addition, the battery management system 20 may control ON/OFF settings or states of the switching unit 14, for example, a relay or a contactor, and may be connected to the plurality of battery cells 10 to monitor a state of each of the plurality of battery cells 10. According to an embodiment, the battery management system 20 may include a battery management apparatus 100 of FIG. 2. According to another embodiment, the battery management system 20 may be a different system from the battery management apparatus 100 of FIG. 2. That is, the battery management apparatus 100 of FIG. 2 may be included in the battery pack 1 or may be configured as another apparatus external to the battery pack 1. In addition, some or all of the operations performed by the battery management apparatus 100 described in this disclosure may alternatively, or additionally, be performed by a battery management system (BMS) included in a vehicle and/or other apparatuses, such as a server, cloud, charger, or charger/discharger.

The higher-level controller 2 may transmit a control signal for the plurality of battery cells 10 to the battery management system 20. Accordingly, the operation of the battery management system 20 may be controlled based on the signal applied from the higher-level controller 2.

During charging of the plurality of battery cells 10, the BMS 20, the battery charging protocol, the controller 120, or other component of the battery pack 1 or battery management apparatus 100 described herein may identify or group the battery cells 10 to be included in one or more SOC classes. In some embodiments, each SOC class may include a grouping of battery cells 10 having a particular state of charge (SOC) value or falling within a range of SOC values.

Each SOC class can include any SOC value and/or any range of SOC values. In one example, a SOC class can include all battery cells 10 having a particular SOC value, such as all battery cells having a 5% SOC or 10% SOC. In another example, a SOC class may comprise all battery cells 10 falling within a particular range of SOC values (e.g., having a SOC of 108-20, 20%-30%, 30%-40%, etc.). In other examples, a SOC class may include all battery cells 10 having SOCs values ranging from 1% to 100% or 0% to 100%.

FIG. 2 is a block diagram showing a battery management apparatus according to an embodiment.

The battery management apparatus 100 may be included a variety of electronic apparatuses for managing, diagnosing, and testing the batteries. According to an embodiment, the battery management apparatus 100 may be included in any one of the following: a battery management system (BMS) inside the battery pack, a battery management server, a computer, and/or a cloud server. According to another embodiment, the battery management apparatus 100 may be included in an apparatus for charge/discharge testing, such as a charge/discharge cycler. The battery management apparatus 100 may be included or used in connection with many other types of devices and apparatuses as well.

As explained throughout this disclosure, the battery management apparatus 100 can be configured to perform or execute various processes for diagnosing one or more abnormal battery conditions. In certain embodiments, the battery management apparatus 100 can diagnose the one or more abnormal battery conditions, at least in part, using resistance values that are derived from voltage measurements acquired while the battery cells of a SOC class are being charged.

The types of abnormal battery conditions diagnosed by the battery management apparatus 100 can vary. In some examples, the battery management apparatus 100 can execute processes for diagnosing lithium precipitation conditions of one or more battery cells 100. Additionally, or alternatively, the battery management apparatus 100 also can be execute processes for diagnosing other types of abnormal battery conditions including, but not limited to, a dendrite growth condition, a short circuit condition, and/or a thermal runaway condition.

Referring to FIG. 2, the battery management apparatus 100 according to an embodiment disclosed in this document may include an information acquisition unit 110 and a controller 120.

The information acquisition unit 110 may acquire a voltage of each of the plurality of battery cells. For example, the information acquisition unit 110 may acquire the voltage of each of the plurality of battery cells in time series. For another example, the information acquisition unit 110 may acquire the voltage of each of the plurality of battery cells that are being charged.

The structure or arrangement of the information acquisition unit 110 can vary based on a configuration of the battery management apparatus 100. In some examples, the battery management apparatus 100 can be directly integrated into a BMS, battery pack 1, or a device that includes the battery pack 1. In this scenario, the information acquisition unit 110 may correspond to one or more voltage measurement sensors that are configured to measure the voltage of the plurality of battery cells. In other examples, the battery management apparatus 100 (or certain components of the battery management apparatus 100) may be incorporated into a remote monitoring system (e.g., a cloud-based remote monitoring server or computing system) that is in communication with the battery pack 1 or device including the battery pack 1. In this scenario, the information acquisition unit 110 may correspond to a processor, a transceiver, and/or a memory storage device (e.g., a memory storage device that stores computing instructions for performing the functions of the information acquisition unit 110) that receives the voltage measurements for the plurality of battery cells. Other configurations of the information acquisition unit 110 also are possible.

The controller 120 may calculate a resistance of each of the plurality of battery cells based on a voltage of each of the plurality of battery cells. For example, when a plurality of battery cells are charged based on a preset charging protocol, the controller 120 may calculate the resistance of each of the plurality of battery cells based on the voltage of each of the plurality of battery cells.

According to an embodiment, the controller 120 may calculate the resistance of each of a plurality of battery cells corresponding to a SOC class including at least one SOC value. For example, the SOC class may include battery cells having a single SOC value or a plurality of SOC values. For another example, the SOC class may include all 100 SOCs from SOC 1 to SOC 100, but is not limited thereto, and may include at least one SOC from SOC 0 to SOC 100. According to an embodiment, when the plurality of battery cells are being charged, the controller 120 may calculate the resistance of each of the plurality of battery cells based on the voltage of each of the plurality of battery cells when the plurality of battery cells reach a particular SOC value included in the SOC class.

According to an embodiment, a charging protocol may be configured to repeat a charging method of charging as much as a first SOC value a first C-rate and resting for a first time. For example, the first SOC value may be a SOC value included in the SOC class. For another example, when the SOC class includes a total of 100 SOC values from SOC 1, SOC 2, SOC 3 to SOC 100, the charging protocol may be configured to repeat the charging method of charging as much as one SOC at the first C-rate and resting for 30 seconds. According to an embodiment, the first C-rate may be 0.3 C, and the first time may be 30 seconds, but are not limited thereto.

In this case, the controller 120 may calculate the resistance of each of the plurality of battery cells while charging the plurality of battery cells at the first C-rate. For example, when charging the plurality of battery cells at the first C-rate, the controller 120 may calculate an amount of change in voltage of each of the plurality of battery cells for a second time. In addition, the controller 120 may calculate the resistance of each of the plurality of battery cells by dividing the change in voltage of each of the plurality of battery cells by a charging current. According to an embodiment, the second time may be one second, but is not limited thereto, and the controller 120 may calculate the resistance of each battery cell based on an amount of change in voltage between a voltage at the time of starting charging at the first C-rate and a voltage after the second time.

According to another embodiment, the charging protocol may be configured to repeat the charging method of charging as much as the first SOC value (e.g., 1%, 5%, etc.) at the first C-rate and charging for a set time at a second C-rate, and the second C-rate may be smaller than the first C-rate. For example, the first SOC value may be a SOC value included in the SOC class. That is, the battery management apparatus 100 according to embodiments disclosed in this document may diagnose each of the plurality of battery cells while the plurality of battery cells are being charged, based on various charging protocols.

In this case, the controller 120 may calculate the resistance of each of the plurality of battery cells while charging the plurality of battery cells at the first C-rate. For example, when charging the plurality of battery cells at the first C-rate, the controller 120 may calculate the amount of change in voltage of each of the plurality of battery cells for the second time. In addition, the controller 120 may calculate the resistance of each of the plurality of battery cells by dividing the change in voltage of each of the plurality of battery cells by the charging current. According to an embodiment, the second time may be one second, but is not limited thereto, and the controller 120 may calculate the resistance of each battery cell based on the amount of change in voltage between a voltage at the time of starting charging at the first C-rate and the voltage after the second time.

According to an embodiment, the charging protocol may include a variety of charging methods that repeat a plurality of C-rates and resting and repeat charging up to the SOC included in the SOC class.

The controller 120 may diagnose each of the plurality of battery cells based on the resistance of each of the plurality of battery cells corresponding to the SOC class. For example, the controller 120 may calculate a first average resistance of each of the plurality of battery cells corresponding to an average of resistances of each of the plurality of battery cells corresponding to the SOC class, and calculate a second average resistance corresponding to an average of the first average resistance of each of the plurality of battery cells. In this case, the controller 120 may diagnose each of the plurality of battery cells based on the first average resistance and the second average resistance of each of the plurality of battery cells. According to an embodiment, the controller 120 may calculate the second average resistance by performing an arithmetic average of the first average resistance of each of the plurality of battery cells.

That is, by diagnosing each of the plurality of battery cells through the first average resistance corresponding to the average of the resistances of each of the plurality of battery cells corresponding to the SOC class, the controller 120 can prevent the occurrence of misdiagnosis due to an error when diagnosing by measuring the voltage at a single SOC. However, when an accuracy of resistance measurement is high, the controller 120 may diagnose each of the plurality of battery cells based on the resistance of the plurality of battery cells corresponding to a single SOC.

Table 1 below illustrates details of an exemplary technique for determining first average resistance values and second average resistance according to certain embodiments.

TABLE 1

| Battery | | | | | 1^{st} Average |
|---|---|---|---|---|---|
| Cells | SOC 1% | SOC 2% | . . . | SOC 100% | Resistance |
| Cell-1 | R1_{SOC1} | R1_{SOC2} | . . . | R1_{SOC100} | R1_{avg} |
| Cell-2 | R2_{SOC1} | R2_{SOC2} | . . . | R2_{SOC100} | R2_{avg} |
| . . . | . . . | . . . | . . . | . . . | . . . |
| Cell-N | RN_{SOC1} | RN_{SOC2} | . . . | RN_{SOC100} | RN_{avg} |
| 2^{nd} Avg. | | | | | SecondAvgRest |
| Rest. | | | | | |

In this example, a charging protocol is applied to a plurality of battery cells included in a SOC class (such as battery cells Cell-1, Cell-2 . . . . Cell-N, where N can be any positive integer value). A resistance value for each battery cell is calculated multiple times as the battery cell is being charged and reaches different SOC values (e.g., SOC % 1, SOC 2%, through SOC 100%). For example, a first resistance value (R1_{SOC1}, R2_{SOC1} . . . . RN_{SOC1}) is calculated for each of the battery cells (Cell-1, Cell-2 . . . . Cell-N) at a first point in time when the battery cells have a first SOC value (SOC 1 %), a second resistance value (R1_{SOC2}, R2_{SCO2} . . . . RN_{SOC2}) is calculated for each of the battery cells at a second point in time when the battery cells have a second SOC value (SOC 2%), etc. In some embodiments, the resistance value for each of the battery cells may be continuously determined or calculated until each of the battery cells is fully charged (e.g., at SOC 100%) and/or up to a predetermined SOC threshold (e.g., at SOC 10%, SOC 50%, etc.).

A first average resistance value is calculated for each of the battery cells based on the resistance values measured or calculated for a corresponding battery cell over time. For example, the first average resistance (R1_{avg}) for Cell-1 may be computed by averaging the resistance values (R1_{SOC1}, R1_{SOC2} . . . . R1_{SOC100}) calculated for the Cell-1 at different SOC levels and/or at different points in time. The first average resistance values for the other cells (e.g., Cell-2 through Cell-N) may be calculated in the same fashion.

In some embodiments, the first average resistance values for the battery cells can be continuously updated over time as new resistance values are determined over time. For example, the first average resistance value for the battery cell can be recomputed or updated each time a resistance value is computed for a given battery cell. At any point in time during the charging of the battery cell, the first average resistance value for the given battery cell may reflect the average of all resistance values derived for the battery cell.

A second average resistance (SecondAvgRest) can be calculated by computing the average of the first average resistance values. For example, the second average resistance may be determined by averaging the first average resistance values (R1_{avg}, R2_{avg}, . . . . RN_{avg}) for Cell-1 through Cell-N. In some examples, the second average resistance can be continuously recalculated over time (e.g., each time a new set of resistance values is computed for a new SOC level).

The exemplary technique for computing the first and second average resistance values illustrated in Table 1 can be varied in many ways. Amongst other things, these resistance calculations can be performed for any number of battery cells, and any number of resistance values can be measured or calculated for each of the battery cells (e.g., in some cases, at least two or more resistance values are calculated for each battery cell). Additionally, while Table 1 provides an example in which the resistance values are determined for each battery cell at one percent SOC value intervals, the resistance values can be measured or calculated at any desired interval (e.g., at .1% intervals, .5% intervals, 2% intervals, 5% intervals, etc.). Additionally, the resistance values for each battery does not need to be continuously calculated up to a SOC level of 100% and can be computed up to any desired SOC level or threshold. Many other variations also are possible.

According to an embodiment, the controller 120 may calculate the first average resistance by removing noise from the resistance of each of the plurality of battery cells corresponding to the SOC class. For example, the controller 120 may calculate the first average resistance by excluding the maximum value and minimum value from the resistances of each of the plurality of battery cells corresponding to the SOC class. For another example, the controller 120 may calculate a regression equation for the resistance of each of the plurality of battery cells based on the resistance of each of the plurality of battery cells corresponding to the SOC class, and may diagnose each of the plurality of battery cells based on the regression equation.

According to an embodiment, the controller 120 may calculate a probability distribution of the first average resistance of each of the plurality of battery cells based on the first average resistance and the second average resistance of each of the plurality of battery cells, and diagnose each of a plurality of battery cells based on the probability distribution. For example, the controller 120 may diagnose a battery cell having the first average resistance that differs from the second average resistance by a set value or more in the probability distribution as an abnormal battery cell. For another example, the controller 120 may diagnose the battery cell having the first average resistance that differs from the second average resistance by a set value or more in the probability distribution as a battery cell in which lithium precipitation has occurred.

According to an embodiment, the controller 120 may calculate a standard deviation of the first average resistance of each of the plurality of battery cells based on the second average resistance. In this case, the controller 120 may diagnose that lithium precipitation has occurred in the battery cell having the first average resistance that differs from the second average resistance by a set deviation or more. For example, the set deviation may be 2 sigma.

Therefore, the battery management apparatus 100 according to an embodiment disclosed in this document can diagnose the plurality of battery cells during charging through a diagnostic charging protocol.

In addition, the battery management apparatus 100 according to an embodiment disclosed in this document may calculate the resistance of each of the plurality of battery cells corresponding to the SOC class including at least one SOC based on the voltage of each of the plurality of battery cells when charging based on the diagnostic charging protocol, and diagnose each of the plurality of battery cells based on the calculated resistance.

In addition, the battery management apparatus 100 according to an embodiment disclosed in this document may calculate the probability distribution of resistance of each of the plurality of battery cells corresponding to the SOC class and diagnose each of the plurality of battery cells based on the calculated probability distribution.

In addition, the battery management apparatus 100 according to an embodiment disclosed in this document may diagnose each of the plurality of battery cells while efficiently charging the plurality of battery cells through various diagnostic charging protocols.

In addition, the battery management apparatus 100 according to an embodiment disclosed in this document may prevent the misdiagnosis due to a measurement error by diagnosing each of the plurality of battery cells based on the average of the resistances of each of the plurality of battery cells measured at various SOCs.

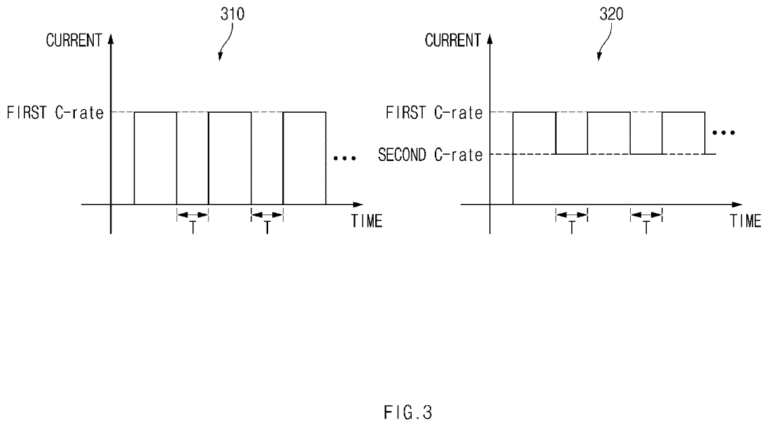

FIG. 3 is a diagram showing an example of a charging protocol according to an embodiment.

Referring to FIG. 3, a first charging protocol 310 may be configured to repeat the charging method of charging as much as the first SOC at the first C-rate and resting for a first time T.

A second charging protocol 320 may be configured to repeat the charging method of charging as much as the first SOC at the first C-rate and charging at the second C-rate for a second time T.

Therefore, the battery management apparatus 100 can diagnose the plurality of battery cells while charging them according to each charging protocol. By diagnosing multiple battery cells during charging, the battery management apparatus 100 can optimize the time for diagnosing a plurality of battery cells and inform a user of a diagnosis result after charging is complete. In some embodiments, a real-time diagnosis result may be provided during the charging process, which can immediately indicate if an abnormal battery condition (e.g., a lithium precipitation condition) is detected during the charging process. For example, when the battery management apparatus 100 has acquired sufficient information to diagnose an abnormal battery condition before the charging process as completed and/or before the battery cells have reached a SOC value of 100%, the diagnosis result can be output prior to the completion of the charging process.

In addition to the charging protocol shown in FIG. 3, the charging protocol may be configured to repeat an operation of charging at various C-rates and then resting or charging at a low C-rate. According to an embodiment, the charging protocol may be configured to repeat the first C-rate, the second C-rate, and resting.

According to various embodiments, the charging protocol may be configured to repeat charging and discharging. In this case, substantially the same technical idea as the charging protocol that repeats charging and resting may be applied.

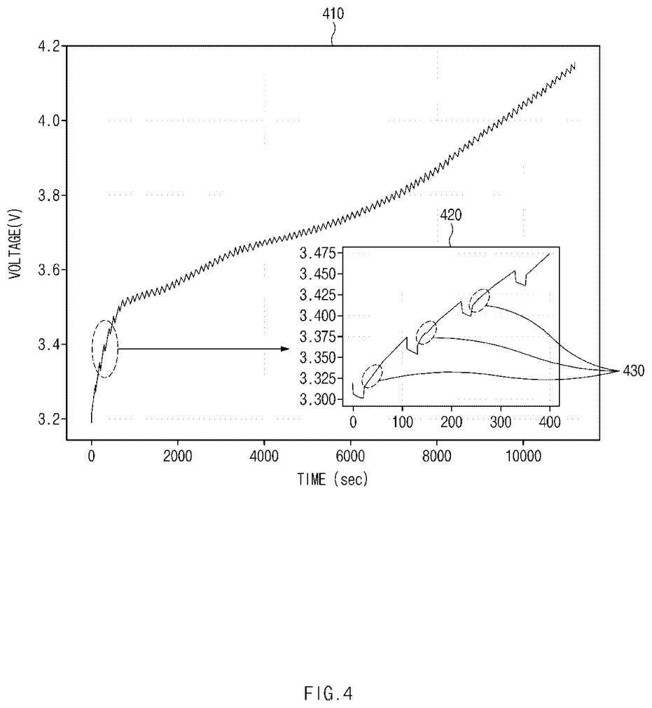

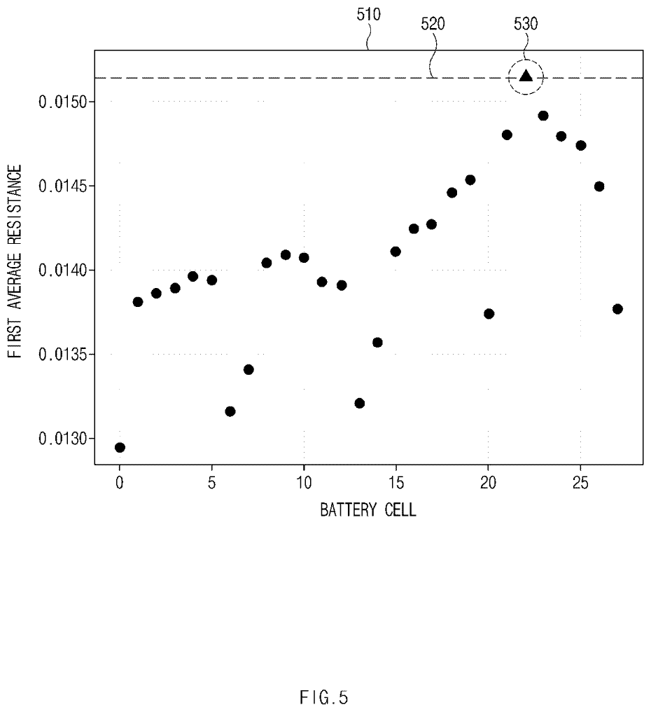

FIGS. 4 and 5 are diagrams showing an example of the battery management apparatus diagnosing a plurality of battery cells according to an embodiment disclosed in this document.

Referring to FIG. 4, the information acquisition unit 110 may acquire voltages 410 of the plurality of battery cells. Although only the voltage of a single battery cell is shown in FIG. 4, the information acquisition unit 110 may acquire the voltages 410 of the plurality of battery cells.

When the plurality of battery cells are charged based on a preset charging protocol, the controller 120 may calculate the voltage of each of the plurality of battery cells corresponding to the SOC class including at least one SOC value based on the voltage 410 of each of the plurality of battery cells.

Referring to some voltages 420 of the voltages 410 of the plurality of battery cells in FIG. 4, the controller 120 may calculate the resistance of each of the plurality of battery cells while charging the plurality of battery cells at a first C-rate 430. According to an embodiment, when charging the plurality of battery cells at the first C-rate, the controller 120 may calculate the amount of change in voltage of each of the plurality of battery cells for the second time, and calculate the resistance of each of the plurality of battery cells by dividing the change in voltage of each of the plurality of battery cells by a charging current. For example, while charging the plurality of battery cells at the first C-rate, the controller 120 may calculate the resistance based on the change in voltage between one second and two seconds after starting charging at the first C-rate, and calculate the resistance based on the amount of change in voltage between zero seconds and one second. That is, the controller 120 may calculate the resistance of each of the plurality of battery cells to correspond to various second times.

The controller 120 may diagnose each of the plurality of battery cells based on the resistance of each of the plurality of battery cells corresponding to the SOC class. For example, the controller 120 may calculate the first average resistance of each of the plurality of battery cells corresponding to the average of resistances of each of the plurality of battery cells corresponding to the SOC class, and calculate the second average resistance corresponding to the average of the first average resistance of each of the plurality of battery cells. In this case, the controller 120 may diagnose each of the plurality of battery cells based on the first average resistance and the second average resistance of each of the plurality of battery cells.

Referring to FIG. 5, the controller 120 may calculate a first average resistance 510 of each of the plurality of battery cells. In addition, the controller 120 may calculate the second average resistance by performing an arithmetic average of the first average resistance 510 of each of the plurality of battery cells, and diagnose each of the plurality of battery cells based on the first average resistance 510 and the second average resistance of each of the plurality of battery cells.

According to an embodiment, the controller 120 may diagnose that lithium precipitation has occurred in the battery cell 530 having the first average resistance that differs from the second average resistance by a set deviation 520 or more.

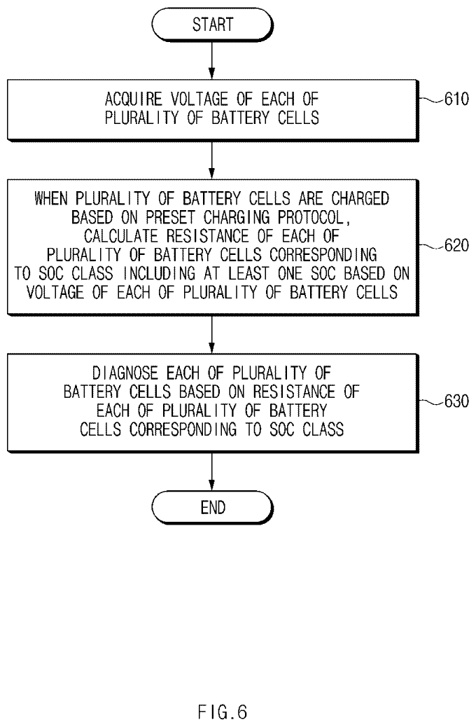

FIG. 6 is a flowchart showing an operating method of the battery management apparatus according to an embodiment disclosed in this document. According to an embodiment, the operations shown in FIG. 6 may be performed through the battery management apparatus 100 of FIG. 2.

Referring to FIG. 6, in operation 610, the information acquisition unit 110 may acquire the voltage of each of the plurality of battery cells. For example, the information acquisition unit 110 may acquire the voltage of each of the plurality of battery cells in time series. For another example, the information acquisition unit 110 may acquire the voltage of each of the plurality of battery cells that are being charged.

In operation 620, when the plurality of battery cells are charged based on a preset charging protocol, the controller 120 may calculate the resistance of each of the plurality of battery cells corresponding to the SOC class including at least one SOC based on the voltage of each of the plurality of battery cells. For example, the SOC class may include a single SOC or a plurality of SOCs. For another example, the SOC class may include all 100 SOCs from SOC 1 to SOC 100, but is not limited thereto, and may include at least one SOC from SOC 0 to SOC 100. According to an embodiment, when the plurality of battery cells are charged the controller 120 may calculate the resistance of each of the plurality of battery cells based on the voltage of each of the plurality of battery cells when the plurality of battery cells reach the SOC included in the SOC class.

According to an embodiment, the charging protocol may be configured to repeat a charging method of charging as much as the first SOC at the first C-rate and resting for the first time. In this case, the controller 120 may calculate the resistance of each of the plurality of battery cells while charging the plurality of battery cells at the first C-rate.

According to another embodiment, the charging protocol may be configured to repeat the charging method of charging as much as the first SOC at the first C-rate and charging for a set time at the second C-rate, and the second C-rate may be smaller than the first C-rate. In this case, the controller 120 may calculate the resistance of each of the plurality of battery cells while charging the plurality of battery cells at the first C-rate.

In operation 630, the controller 120 may diagnose each of the plurality of battery cells based on the resistance of each of the plurality of battery cells corresponding to the SOC class. For example, the controller 120 may diagnose each of the plurality of battery cells by calculating an average of resistances of each of the plurality of battery cells corresponding to the SOC class. According to an embodiment, the controller 120 may diagnose each of the plurality of battery cells by comparing the resistance of each of the plurality of battery cells with that of other battery cells.

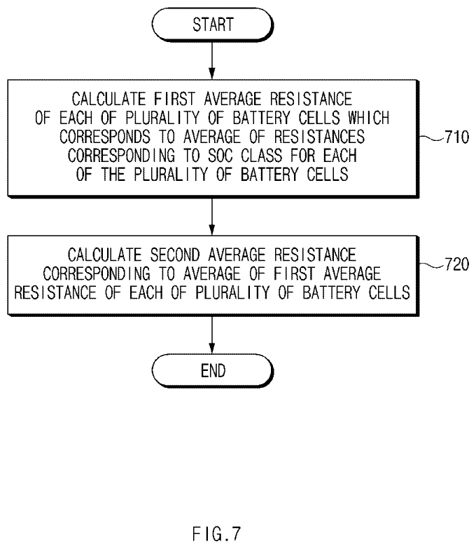

FIGS. 7 to 10 are flowcharts specifically showing the operating method of the battery management apparatus according to embodiments described herein. According to some embodiments, some or all of the operations shown in FIGS. 7 to 10 may be performed through the battery management apparatus 100 of FIG. 2.

Referring to FIG. 7, in operation 710, the controller 120 may calculate the first average resistance of each of the plurality of battery cells which corresponds to the average of the resistances corresponding to the SOC class, for each of the plurality of battery cells.

In operation 720, the controller 120 may calculate the second average resistance corresponding to the average of the first average resistance of each of the plurality of battery cells. In this case, the controller 120 may diagnose each of the plurality of battery cells based on the first average resistance and the second average resistance of each of the plurality of battery cells.

That is, by diagnosing each of the plurality of battery cells through the first average resistance which corresponds to the average of the resistances of each of the plurality of battery cells corresponding to the SOC class, the controller 120 can prevent the occurrence of misdiagnosis due to an error when diagnosing by measuring the voltage at a single SOC. However, when the accuracy of resistance measurement is high, the controller 120 may diagnose each of the plurality of battery cells based on the resistance of the plurality of battery cells corresponding to a single SOC.

According to an embodiment, operations 710 and 720 may be performed in connection with performing operation 630 of FIG. 6.

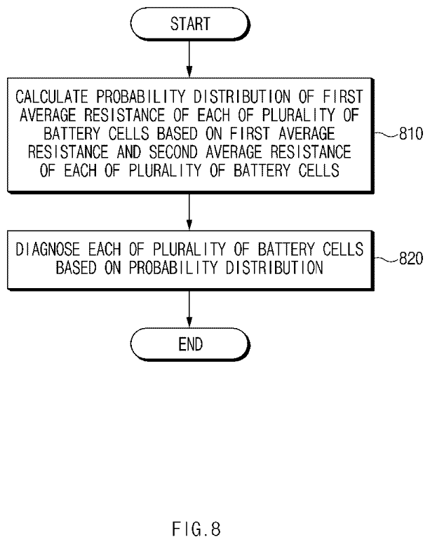

Referring to FIG. 8, in operation 810, the controller 120 may calculate a probability distribution of the first average resistance of each of the plurality of battery cells based on the first average resistance and the second average resistance of each of the plurality of battery cells.

In operation 820, the controller 120 may diagnose each of the plurality of battery cells based on the probability distribution. For example, the controller 120 may diagnose a battery cell having the first average resistance that differs from the second average resistance by a set value or more in the probability distribution as an abnormal battery cell. For another example, the controller 120 may diagnose the battery cell having the first average resistance that differs from the second average resistance by a set value or more in the probability distribution as a battery cell in which lithium precipitation has occurred.

According to an embodiment, operations 810 and 820 may be performed in connection with operation 630 of FIG. 6.

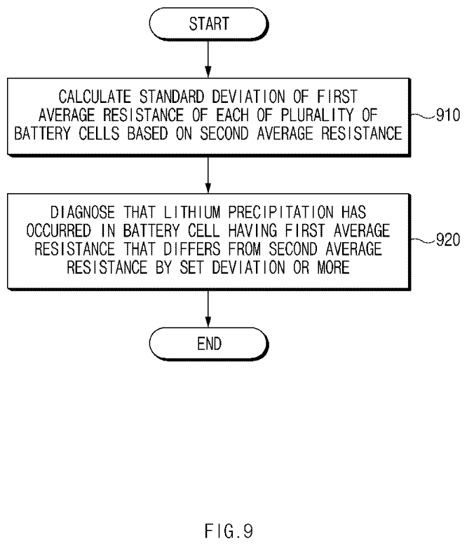

Referring to FIG. 9, in operation 910, the controller 120 may calculate the standard deviation of the first average resistance of each of the plurality of battery cells based on the second average resistance.

In operation 920, the controller 120 may diagnose that the lithium precipitation has occurred in the battery cell having the first average resistance that differs from the second average resistance by a set deviation or more. For example, the set deviation may be 2 sigma. According to an embodiment, operations 910 and 920 may be performed in connection with operation 630 of FIG. 6.

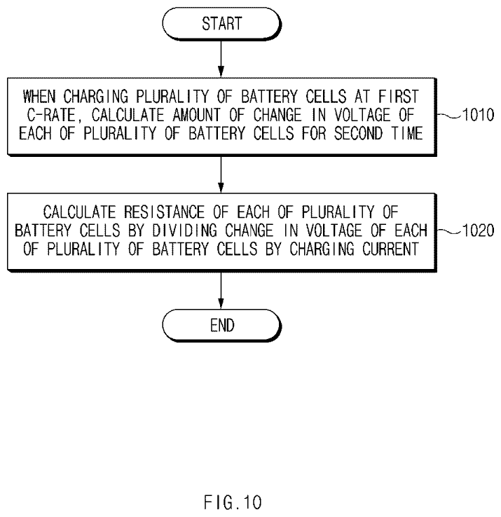

Referring to FIG. 10, in operation 1010, when charging the plurality of battery cells at the first C-rate, the controller 120 may calculate the amount of change in voltage of each of the plurality of battery cells for the second time. According to an embodiment, the second time may be one second, but is not limited thereto, and the controller 120 may calculate the resistance of each battery cell based on the amount of change in voltage between a voltage at the time of starting charging at the first C-rate and a voltage after the second time.

In operation 1020, the controller 120 may calculate the resistance of each of the plurality of battery cells by dividing the change in voltage of each of the plurality of battery cells by the charging current.

Operation 1010 and operation 1020 may be performed in connection with operation 620 of FIG. 6.

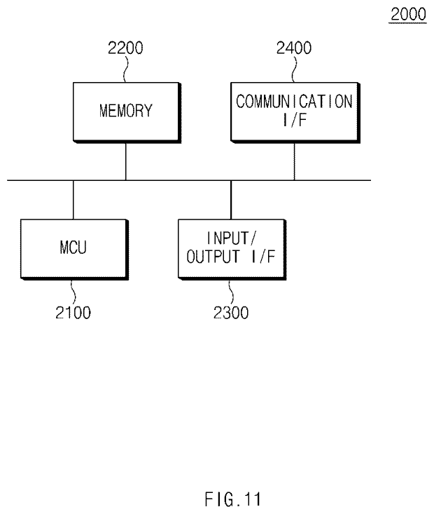

FIG. 11 is a block diagram showing a hardware configuration of a computing system for performing the operating method of the battery management apparatus according to an embodiment disclosed in this document.

Referring to FIG. 11, a computing system 2000 according to an embodiment disclosed in this document may include an MCU 2100, a memory 2200, an input/output I/F 2300, and a communication I/F 2400.

The MCU 2100 may be a processor adapted to cause various programs (e. g., a charging protocol execution program, a battery cell resistance calculation program, a battery cell diagnosis program, etc.) stored in the memory 2200 to be executed, process various information including the resistance of each of the plurality of battery cells, the average resistance thereof, the diagnosis result of each of the plurality of battery cells, etc. through these programs, and perform functions of the controller included in the battery management apparatus shown in FIG. 2 described above.

The memory 2200 may store various programs such as the charging protocol execution program, the battery cell resistance calculation program, the battery cell diagnosis program, etc. In addition, the memory 2200 may store various information, including the resistance of each of the plurality of battery cells, the average resistance thereof, the diagnosis result of each of the plurality of battery cells, etc.

A plurality of such memories 2200 may be provided as needed. The memory 2200 may be a volatile memory or a non-volatile memory. The memory 2200 as the volatile memory may be a RAM, a DRAM, an SRAM, etc. The memory 2200 as the non-volatile memory may be a ROM, a PROM, an EAROM, an EPROM, an EEPROM, a flash memory, etc. The examples of memories 2200 listed above are merely examples and are not limited to these examples.

The input/output I/F 2300 may provide an interface that allows data to be transmitted and received by connecting the MCU 2100 with input devices such as a keyboard, a mouse, and a touch panel (not shown) and an output device such as a display (not shown).

The communication I/F 2400 is a configuration that can transmit and receive various data with a server, and may be various devices that can support communication wirelessly or in a wired manner. For example, through the communication I/F 2400, the battery management apparatus can transmit and receive various information, including the resistance of each of the plurality of battery cells, the average resistance thereof, the diagnosis result of each of the plurality of battery cells, etc. from a separately provided external server.

In this way, the computer program according to an embodiment disclosed in this document may be recorded in the memory 2200 and processed by the MCU 2100, thereby capable of being implemented as a module that performs each function shown in FIG. 2, for example.

The battery management apparatus and operating method of the same according to an embodiment of the present disclosure can diagnose a plurality of battery cells during charging through a diagnostic charging protocol.

The battery management apparatus and operating method of the same according to the embodiment of the present disclosure can calculate the resistance of each of the plurality of battery cells corresponding to a SOC class including at least one SOC based on the voltage of each of the plurality of battery cells when charging based on a diagnostic charging protocol, and diagnose each of the plurality of battery cells based on the calculated resistance.

The battery management apparatus and operating method of the same according to the embodiment of the present disclosure can calculate a probability distribution of resistance of each of a plurality y of battery cells corresponding to a SOC class, and diagnose each of the plurality of battery cells based on the calculated probability distribution.

The battery management apparatus and operating method of the same according to the embodiment of the present disclosure can diagnose each of the plurality of battery cells while efficiently charging the plurality of battery cells through various diagnostic charging protocols.

In addition, various effects that can be directly or indirectly grasped through the embodiments of the present disclosure may be provided.

The description as above is merely an exemplary description of the technical ideas disclosed in this document. Those of ordinary skill in the technical field to which the embodiments disclosed in this document pertain will be able to make various modifications and variations thereto without departing from the essential characteristics of the embodiments disclosed in this document.

Therefore, the embodiments disclosed in this document are not intended to limit the technical ideas disclosed in this document, but rather to explain the embodiments, and the scope of the technical ideas disclosed in this document is not limited by these embodiments. The scope of protection of the technical ideas disclosed in this document shall be interpreted in accordance with the claims below, and all technical ideas within the equivalent scope shall be interpreted as being included within the scope of rights of this document.

While the present disclosure has been shown and described in connection with the exemplary embodiments, it will be apparent to those skilled in the art that modifications and variations can be made without departing from the spirit and scope of the disclosure as defined by the appended claims.

What is claimed is:

1. A system for diagnosing an abnormal battery condition comprising:
an information acquisition unit configured to acquire voltage values for each of a plurality of battery cells associated with a state of charge (SOC) class, wherein the voltage values are determined while the plurality of battery cells are being charged; and
a controller configured to:
determine a resistance value for each of the plurality of battery cells associated with the SOC class based on the voltage values acquired during charging of the plurality of battery cells; and
detect whether an abnormal battery condition is present for each of the plurality of battery cells associated with the SOC class based, at least in part, on the resistance value determined for each of the plurality of battery cells.

2. The system of claim 1, wherein detecting whether the abnormal battery condition is present includes detecting whether a lithium precipitation condition is present for each of the plurality of battery cells associated with the SOC class based, at least in part, on the resistance value determined for each of the plurality of battery cells associated with the Soc class.

3. The system of claim 1, wherein the controller is further configured to:
determine first average resistance values for the plurality of battery cells associated with the SOC class, wherein each first average resistance value is derived from a plurality of resistance values measured for a corresponding battery cell;
determine a second average resistance value for the plurality of battery cells associated with the SOC class, wherein the second average resistance value is derived by averaging the first average resistance values for the plurality of battery cells; and
for each of the plurality of battery cells associated with the SOC class, detect whether the abnormal battery condition is present based, at least in part, on the first average resistance value for the corresponding battery cell and the second average resistance value calculated across the plurality of battery cells.

4. The system of claim 3, wherein the controller is further configured to:
for each of the plurality of battery cells associated with the SOC class, determine a probability distribution based on the plurality of resistance values measured for a corresponding battery cell and the second average resistance value calculated across the plurality of battery cells; and
detect whether the abnormal battery condition is present for each of the plurality of battery cells based, at least in part, on the probability distribution determined for the corresponding battery cell.

5. The system of claim 3, wherein the controller is further configured to:
for each of the plurality of battery cells associated with the SOC class, determine a standard deviation based on the plurality of resistance values measured for a corresponding battery cell and the second average resistance value calculated across the plurality of battery cells; and
detect whether the abnormal battery condition is present for each of the plurality of battery cells based, at least in part, on the standard deviation.

6. The system of claim 3, wherein:
for each of the plurality of battery cells associated with the SOC class, the plurality of resistance values for the corresponding battery cell are determined when the corresponding battery cell reaches different SOC values during charging; and
the first average resistance value for the corresponding battery cell is based on the plurality of resistance values obtained at the different SOC values.

7. The system of claim 3, wherein:
the abnormal condition corresponds to a lithium precipitation condition; and
the controller is configured to detect whether the lithium precipitation condition is present in each of the plurality of battery cells using the first average resistance value for the corresponding battery cell and the second average resistance value calculated across the plurality of battery cells.

8. The system of claim 1, wherein:
the plurality of battery cells associated with the SOC class are charged according to a charging protocol;
the charging protocol is configured to repeatedly transition between: a) a charging state in which the plurality of battery cells are charged at a first C-rate; and b) a resting state; and
the controller is configured to determine the resistance value for each of the plurality of battery cells while charging the plurality of battery cells at the first C-rate in the charging state.

9. The system of claim 7, wherein the controller is further configured to:
determine an amount of change between the voltage values acquired for each of the plurality of battery cells during a first charging state for a first time period and a second charging state for a second time period; and
determine the resistance value for each of the plurality of battery cells based on a charging current applied to each of the plurality of battery cells and the change in voltage values for each of the plurality of battery cells.

10. The system of claim 1, wherein:
the plurality of battery cells associated with the SOC class are charged according to a charging protocol;
the charging protocol is configured to repeatedly transition between: a) a first charging state in which the plurality of battery cells are charged at a first C-rate; and b) a second charging state in which the plurality of battery cells are charged at a second C-rate;
the second C-rate is smaller than the first C-rate; and
the controller is configured to determine the resistance value for each of the plurality of battery cells while charging the plurality of battery cells at the first C-rate in the first charging state.

11. The system of claim 1, wherein:
the information acquisition unit and the controller are incorporated into a battery management system (BMS) for a battery pack that comprises the plurality of battery cells; or
the information acquisition unit and the controller are incorporated into a cloud server, battery management server, or computing device that is external to the battery pack that comprises the plurality of battery cells.

12. A method for diagnosing an abnormal battery condition comprising:
acquiring voltage values for each of the plurality of battery cells associated with a state of charge (SOC) class, wherein the voltage values are determined while the plurality of battery cells are being charged;
determining a resistance value for each of the plurality of battery cells associated with the SOC class based on the voltage values acquired during charging of the plurality of battery cells; and
detecting whether an abnormal battery condition is present for each of the plurality of battery cells associated with the SOC class based, at least in part, on the resistance value determined for each of the plurality of battery cells.

13. The method of claim 12, wherein detecting whether the abnormal battery condition is present includes detecting whether a lithium precipitation condition is present for each of the plurality of battery cells associated with the SOC class based, at least in part, on the resistance value determined for each of the plurality of battery cells associated with the SOC class.

14. The method of claim 12, wherein the method further comprises:
determining first average resistance values for the plurality of battery cells associated with the SOC class, wherein each first average resistance value is derived from a plurality of resistance values measured for a corresponding battery cell;
determining a second average resistance value for the plurality of battery cells associated with the SOC class, wherein the second average resistance value is derived by averaging the first average resistance values for the plurality of battery cells; and
for each of the plurality of battery cells associated with the SOC class, detecting whether the abnormal battery condition is present based, at least in part, on the first average resistance value for the corresponding battery cell and the second average resistance value calculated across the plurality of battery cells.

15. The method of claim 14, wherein the method further comprises:
for each of the plurality of battery cells associated with the SOC class, determining a probability distribution based on the plurality of resistance values measured for a corresponding battery cell and the second average resistance value calculated across the plurality of battery cells; and
detecting whether the abnormal battery condition is present for each of the plurality of battery cells based, at least in part, on the probability distribution determined for the corresponding battery cell.

16. The method of claim 14, wherein the method further comprises:
for each of the plurality of battery cells associated with the SOC class, determining a standard deviation based on the plurality of resistance values measured for a corresponding battery cell and the second average resistance value calculated across the plurality of battery cells; and
detecting whether the abnormal battery condition is present for each of the plurality of battery cells based, at least in part, on the standard deviation.

17. The method of claim 14, wherein the plurality of resistance values for the corresponding battery cell are determined when the corresponding battery cell reaches different SOC values during charging, and the first average resistance value for the corresponding battery cell is based on the plurality of resistance values obtained at the different SOC values.

18. The method of claim 12, further comprising:
charging the plurality of battery cells associated with the SOC class according to a charging protocol, wherein the charging protocol is configured to repeatedly transition between: a) a charging state in which the plurality of battery cells are charged at a first C-rate; and b) a resting state;
determining an amount of change between the voltage values acquired for each of the plurality of battery cells during a first charging state for a first time period and a second charging state for a second time period; and
determining the resistance value for each of the plurality of battery cells based on a charging current applied to each of the plurality of battery cells and the change in voltage values for each of the plurality of battery cells.

19. The method of claim 12, further comprising:
charging the plurality of battery cells associated with the SOC class according to a charging protocol, wherein:
the charging protocol is configured to repeatedly transition between: a) a first charging state in which the plurality of battery cells are charged at a first C-rate;
and b) a second charging state in which the plurality of battery cells are charged at a second C-rate; and
the second C-rate is smaller than the first C-rate; and
determining the resistance value for each of the plurality of battery cells while charging the plurality of battery cells at the first C-rate in the first charging state.

20. A system for diagnosing a lithium precipitation condition comprising:
an information acquisition unit configured to acquire voltage values for each of a plurality of battery cells associated with a state of charge (SOC) class, wherein the voltage values are determined while the plurality of battery cells are being charged; and
a controller configured to:
determine a resistance value for each of the plurality of battery cells associated with the SOC class based on the voltage values acquired during charging of the plurality of battery cells; and
detect whether a lithium precipitation condition is present for each of the plurality of battery cells associated with the SOC class based, at least in part, on the resistance value determined for each of the plurality of battery cells.
